(19) United States
(12) Patent Application Publication
(10) Pub. No.: US 2024/0312958 A1
(43) Pub. Date: Sep. 19, 2024

(54) SEMICONDUCTOR DEVICE

(71) Applicant: Kioxia Corporation, Tokyo (JP)

(72) Inventor: Toshimitsu ARAI, Chigasaki Kanagawa (JP)

(21) Appl. No.: 18/592,442

(22) Filed: Feb. 29, 2024

(30) Foreign Application Priority Data
Mar. 15, 2023 (JP) 2023-041094

(51) Int. Cl. H01L 25/065; H01L 23/00

(52) U.S. Cl. CPC H01L 25/0657; H01L 24/32; H01L 24/33; H01L 24/48; H01L 24/73; H01L 2224/32145; H01L 2224/32225; H01L 2224/33181; H01L 2224/48145; H01L 2224/48225; H01L 2224/73265; H01L 2225/06562

(57) ABSTRACT

According to one embodiment, a semiconductor device comprises: a first semiconductor chip on which a first adhesive is attached to a rear surface thereof; and a second semiconductor chip on which a second adhesive is attached to a rear surface thereof, wherein the second semiconductor chip is attached to a front surface of the first semiconductor chip via the second adhesive, the second semiconductor chip has an overhang region that does not overlap the first semiconductor chip when viewed in a first direction, and the first adhesive includes a base portion and also includes an extension portion that extends in a second direction from the base portion of the first adhesive to beyond an edge of the first semiconductor chip, at least a part of the extension portion of the first adhesive overlapping the overhang region of the second semiconductor chip when viewed in the first direction.

### CROSS-REFERENCE TO RELATED APPLICATION

This application is based upon and claims the benefit of priority from Japanese Patent Application No. 2023-041094, filed Mar. 15, 2023, the entire contents of which are incorporated herein by reference.

### FIELD

Embodiments described herein relate generally to a semiconductor device.

### BACKGROUND

A semiconductor device in which a plurality of semiconductor chips are stacked and mounted is known.

### DESCRIPTION OF THE DRAWINGS

FIG. 1 is a cross-sectional view schematically showing a semiconductor device according to a first embodiment.

FIG. 2 is a diagram showing an extension portion of a first film-like adhesive according to the first embodiment.

FIG. 3 is a flowchart showing manufacturing steps of the semiconductor device according to the first embodiment.

FIG. 4 is a flowchart showing manufacturing steps of the semiconductor device according to the first embodiment.

FIG. 5A is a cross-sectional view schematically showing the manufacturing step of the semiconductor device according to the first embodiment.

FIG. 5B is a cross-sectional view schematically showing the manufacturing step of the semiconductor device according to the first embodiment.

FIG. 5C is a cross-sectional view schematically showing the manufacturing step of the semiconductor device according to the first embodiment.

FIG. 5D is a cross-sectional view schematically showing the manufacturing step of the semiconductor device according to the first embodiment.

FIG. 5E is a cross-sectional view schematically showing the manufacturing step of the semiconductor device according to the first embodiment.

FIG. 5F is a cross-sectional view schematically showing the manufacturing step of the semiconductor device according to the first embodiment.

FIG. 5G is a cross-sectional view schematically showing the manufacturing step of the semiconductor device according to the first embodiment.

FIG. 6 is a diagram showing a positional relationship between the extension portion and a pressing surface of a mount collet according to the first embodiment.

FIG. 7 is a cross-sectional view schematically showing a semiconductor device according to a second embodiment.

FIG. 8 is a diagram showing a positional relationship between an extension portion and a pad according to the second embodiment.

FIG. 9 is a cross-sectional view schematically showing a semiconductor device according to a third embodiment.

FIG. 10 is a cross-sectional view schematically showing a semiconductor device according to a fourth embodiment.

### DETAILED DESCRIPTION

Embodiments provide a semiconductor device capable of being compressed (made thin) while preventing cracking of a semiconductor chip therein.

In general, according to one embodiment, the semiconductor device comprises a first semiconductor chip on which a first adhesive having an insulating property is attached to a rear surface thereof; and a second semiconductor chip on which a second adhesive having an insulating property is attached to a rear surface thereof, wherein the second semiconductor chip is attached to a front surface of the first semiconductor chip via the second adhesive, the second semiconductor chip has an overhang region that does not overlap the first semiconductor chip when viewed in a first direction orthogonal to the front surface of the first semiconductor chip, and the first adhesive includes a base portion that covers the entire rear surface of the first semiconductor chip and also includes an extension portion that extends in a second direction parallel to the front surface of the first semiconductor chip, from the base portion of the first adhesive to beyond an edge of the first semiconductor chip, at least a part of the extension portion of the first adhesive overlapping the overhang region of the second semiconductor chip when viewed in the first direction.

Hereinafter, embodiments will be described with reference to the accompanying drawings.

In the following description, an XYZ coordinate system, which is an example of a rectangular coordinate system, is used. That is, a plane parallel to a front surface of a wiring board 10 of a semiconductor device 100 is defined as an XY plane, and a direction orthogonal to the XY plane is defined as a Z-axis. In addition, two directions orthogonal to each other in the XY plane are defined as an X-axis and a Y-axis. In each drawing, one side (an upper side of the drawing relative to the Z-axis) is referred to as an upper side, and the other side (a lower side of the drawing relative to the Z-axis) is referred to as a lower side. In addition, as used herein, “in the X direction” means along the X-axis (in either direction thereof), “in the Y direction” means along the Y-axis (in either direction thereof), and “in the Z direction” means along the Z-axis (in either direction thereof). In addition, in the following description, a structure will be described based on an XZ cross section, but the same structure may be used in a cross section other than the XZ cross section, such as a YZ cross section.

### First Embodiment

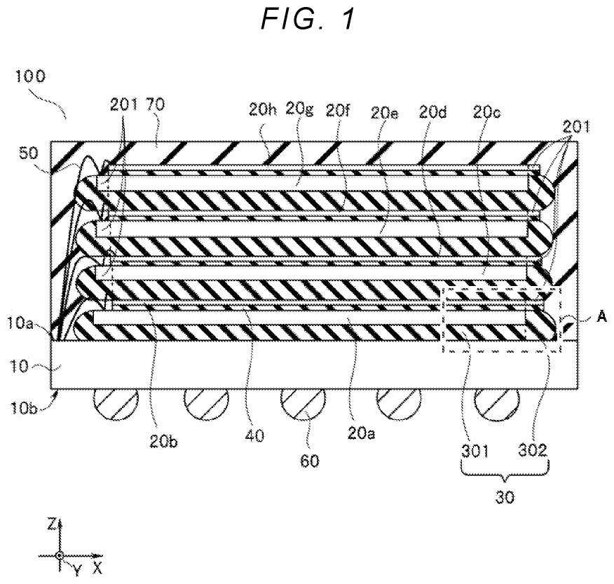

FIG. 1 is a cross-sectional view schematically showing a semiconductor device according to a first embodiment. Size ratios between elements of FIG. 1 are different from actual ratios of the semiconductor device. The semiconductor device 100 is, for example, a semiconductor package in which a semiconductor chip mounted on a wiring board is sealed with a mold resin. The semiconductor device 100 includes a wiring board 10, semiconductor chips 20a-20h, a first film-like adhesive 30, a second film-like adhesive 40, a conductive wire 50, a solder ball 60, and a mold resin 70. The mold resin 70 is an example of a sealing resin.

The wiring board 10 is, for example, an insulating resin wiring board or a ceramic wiring board, and a wiring layer (not shown) is provided on the front surface of the wiring board 10 or inside the wiring board 10. Specifically, for example, a printed wiring board with a glass-epoxy resin or the like may be used. Alternatively, a silicon interposer, a lead frame, or the like may be used. The wiring board 10 includes a first surface 10a and a second surface 10b. External terminals for a ball grid array (BGA) package (protruding terminals formed of solder balls or the like) or an external terminal for a land grid array (LGA) package (metal lands formed of metal plating or the like) are formed on the second surface 10b. It is noted that the external terminals are not shown.

A plurality of semiconductor chips 20a to 20h are mounted on the first surface 10a of the wiring board 10. Hereinafter, when it is not necessary to distinguish between the semiconductor chips 20a to 20h, the semiconductor chips 20a to 20h are simply referred to in aggregate as semiconductor chips 20, and one of the semiconductor chips 20 is referred to as a semiconductor chip 20. The semiconductor chip 20 is, for example, a NAND flash memory chip. Each semiconductor chip 20 is a thin plate having a rectangular shape in a plan view. The semiconductor chip 20 and the wiring board 10 are electrically connected by the conductive wire 50. The semiconductor chip 20 may be electrically connected to the wiring board 10 via others of the semiconductor chips 20. The conductive wire 50 is connected to an upper surface of a pair of surfaces of the semiconductor chip 20, the upper surface being substantially parallel to the XY plane. In the following description, a surface of the semiconductor chip 20 to which the conductive wire 50 is connected is referred to as a “front surface”. In addition, a surface of the semiconductor chip 20 facing the “front surface” is referred to as a “rear surface”.

The plurality of semiconductor chips 20 are stacked and disposed on the first surface 10a such that each of the front surfaces of the semiconductor chips 20 are parallel to the first surface 10a of the wiring board 10. In FIG. 1, the semiconductor chips 20 are disposed in a stacked manner in one direction (up in the Z direction). The thicknesses of the four semiconductor chips 20b, 20d, 20f, and 20h are thinner than the other four semiconductor chips 20a, 20c, 20c, and 20g, and the flexural strength of the four semiconductor chips 20b, 20d, 20f, and 20h tends to be lower. Two of the semiconductor chips 20 disposed side by side in the Z direction are offset in the X direction. That is, when the two semiconductor chips are viewed from the lower side, the two semiconductor chips disposed side by side in the Z direction are disposed so that a part of the upper one of the two semiconductor chips is exposed from an outer periphery of the lower one of the two semiconductor chips. In the following description, the exposed region is referred to as an overhang region 201.

The semiconductor chip 20 may be, for example, a semiconductor chip such as a NAND flash memory, but is not limited thereto, and any semiconductor chip may be used. In addition, in FIG. 1, a structure in which eight semiconductor chips 20 are stacked is described, but any amount of two or more semiconductor chips may be stacked.

The entire rear surface of the semiconductor chip 20 is covered with any one of the first film-like adhesive 30 and the second film-like adhesive 40. The first film-like adhesive 30 and the second film-like adhesive 40 are tape-like adhesives including a resin adhesive component containing a thermosetting resin (for example, an epoxy-based resin, a polyimide-based resin, an acrylic-based resin, or a resin obtained by mixing these resins). The first film-like adhesive 30 is formed using a thick film referred to as film on wire (FOW) or film on die (FOD). The second film-like adhesive 40 is formed using a thin film referred to as die attach film (DAF). The FOW and the FOD are film-like adhesives having a lower viscosity than the DAF and being capable of embedding the conductive wire 50 and the semiconductor chip 20. The thicknesses of the FOW and the FOD are about 40 to 150 μm. Meanwhile, the thickness of the DAF is 25 μm or less. The FOW, FOD, and DAF are used to bring objects attached to the upper and lower sides of the film-like adhesives into close contact with each other by applying heat and a load. The first film-like adhesive 30 and the second film-like adhesive 40 have insulating properties.

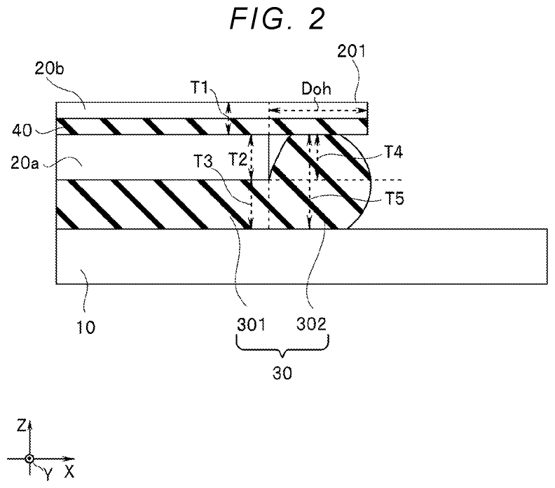

For example, in the semiconductor device 100 shown in FIG. 1, the first film-like adhesive 30 is attached to the rear surfaces of the semiconductor chips 20a, 20c, 20c, and 20g, and the second film-like adhesive 40 is attached to the rear surfaces of the semiconductor chips 20b, 20d, 20f, and 20h. The first film-like adhesive 30 includes a base portion 301 and an extension portion 302. The base portion 301 is a portion that covers the rear surface of the semiconductor chip 20. The extension portion 302 is a portion that protrudes outward from a peripheral edge of the semiconductor chip 20, the peripheral edge contacting an upper surface of the base portion 301. At least a part of the extension portion 302 is in contact with the overhang region 201 of another of the semiconductor chips 20, specifically with that of the semiconductor chip 20 that is directly above the semiconductor chip 20 to which the base portion 301 is attached, via the second film-like adhesive 40. The structure of the extension portion 302 will be described in detail with reference to FIG. 2.

FIG. 2 is a diagram showing an extension portion of the first film-like adhesive 30 according to the first embodiment. FIG. 2 is an enlarged sectional view of a portion A of FIG. 1. In FIG. 2, the semiconductor chips 20c to 20h, the first film-like adhesive 30 and the second film-like adhesive 40 provided on the semiconductor chips 20c to 20h, the conductive wires 50, and the mold resin 70 are not shown. The lower semiconductor chip 20a of the semiconductor chips 20a and 20b is adhered to the wiring board 10 by the first film-like adhesive 30. The upper semiconductor chip 20b is adhered to the semiconductor chip 20a via the second film-like adhesive 40. The semiconductor chip 20b is offset to one side (the right side of FIG. 2) in the X direction with respect to the semiconductor chip 20a. Therefore, the overhang region 201 is present on one side in the X direction in the semiconductor chip 20b. An offset ratio of the semiconductor chip 20b with respect to the semiconductor chip 20a, specifically, the ratio of the thickness T1 from the lower surface of the film-like adhesive 40 to the front surface of the semiconductor chip 20b, with respect to the length Doh of the overhang region 201 of the semiconductor chip 20b, is preferably set to approximately 0.13 or more. For example, when T1=40 μm, it is preferable to set Doh to be less than or equal to approximately 300 μm.

The first film-like adhesive 30 attached to the rear surface of the semiconductor chip 20a has the base portion 301 and the extension portion 302. The extension portion 302 is formed below the overhang region 201. The extension portion 302 is thicker than the base portion 301, and, as shown in FIG. 2, a thickness T5 of the thickest portion of the extension portion 302 is substantially the same as a sum of a thickness T3 of the base portion 301 and a thickness T2 of the semiconductor chip 20a. As shown in FIG. 2, a void may be present between the extension portion 302 and the side surface of the semiconductor chip 20a, and as shown in FIG. 1, the extension portion 302 and the side surface of the semiconductor chip 20a may be in close contact with each other.

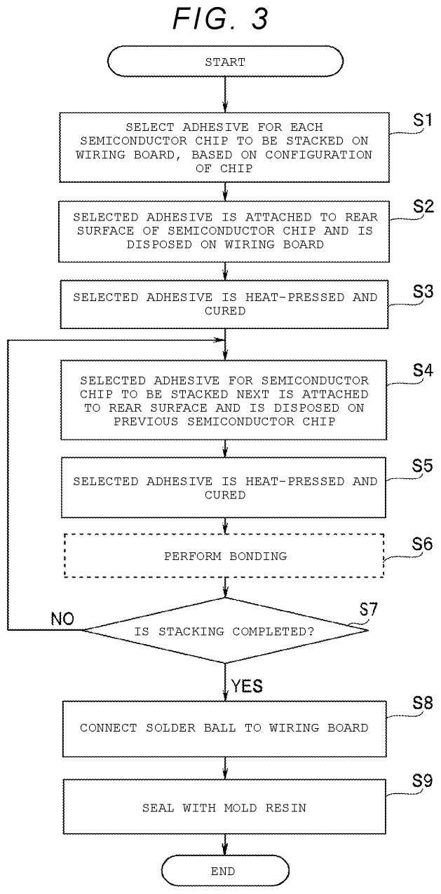

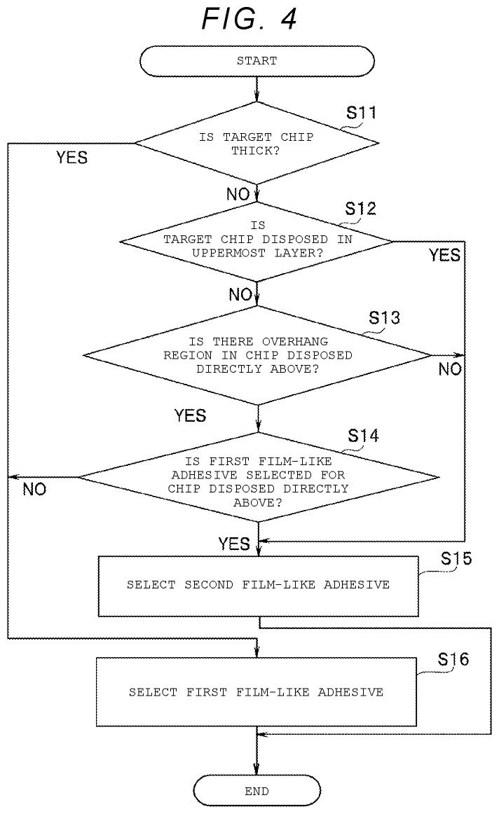

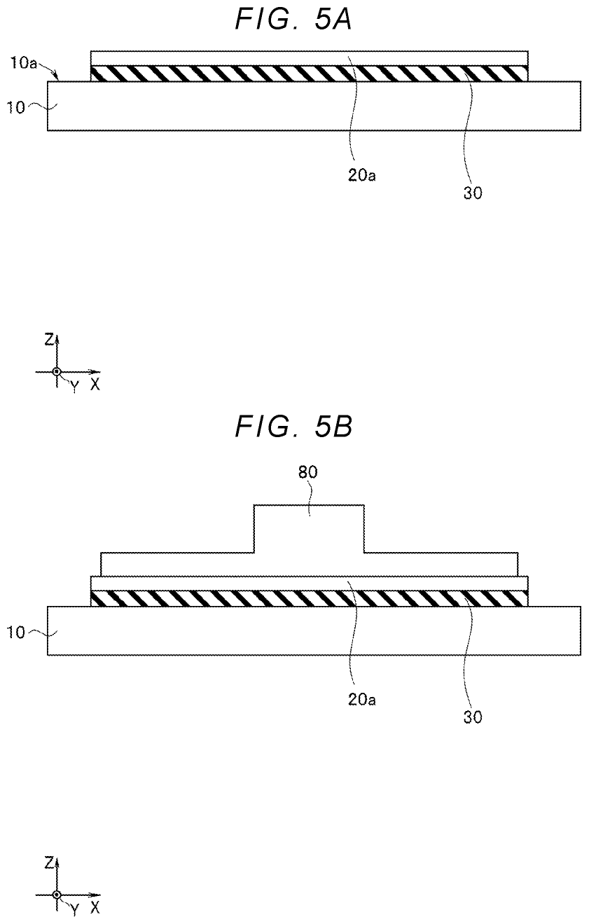

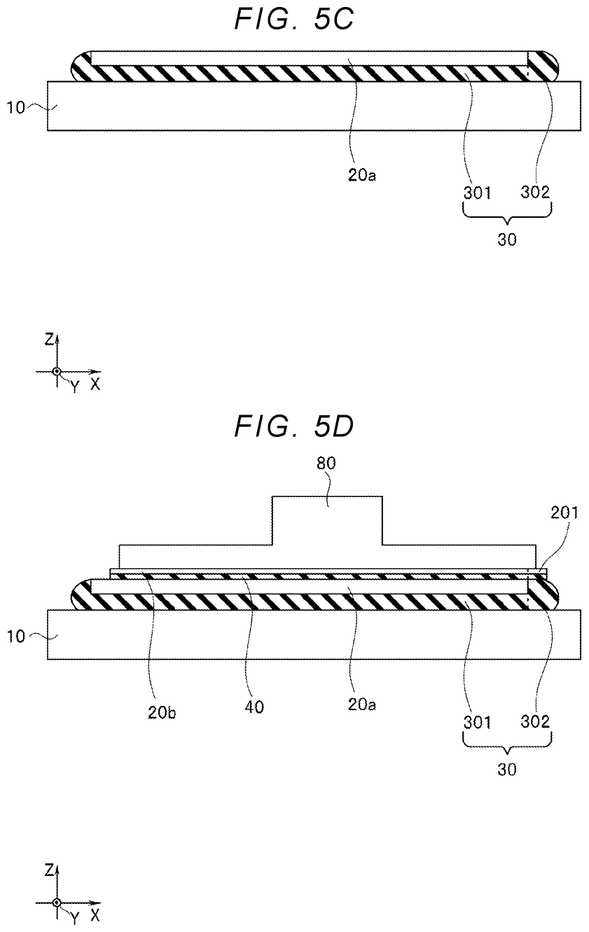

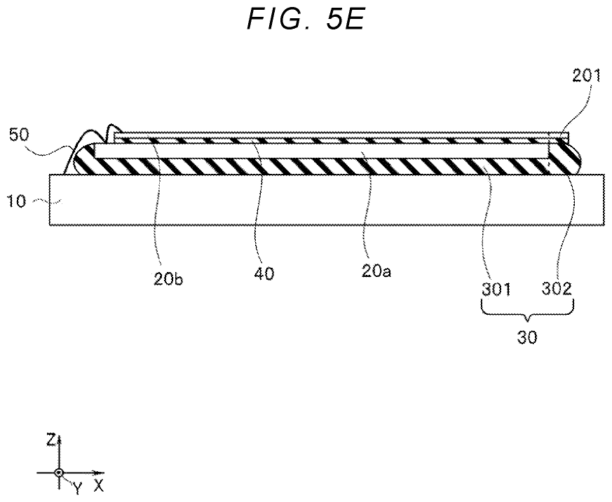

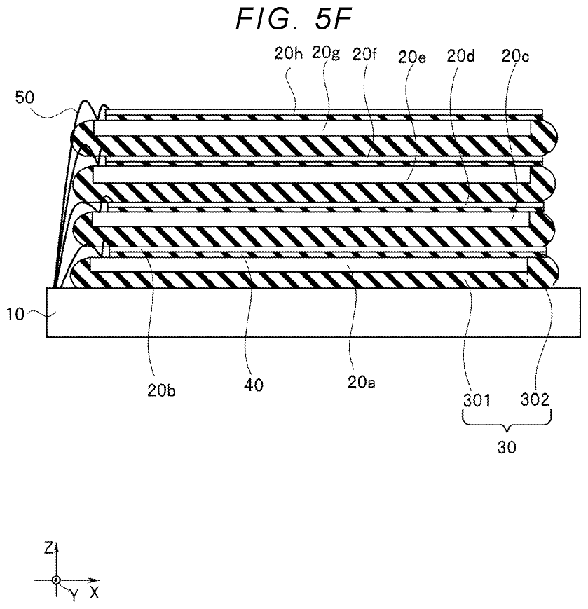

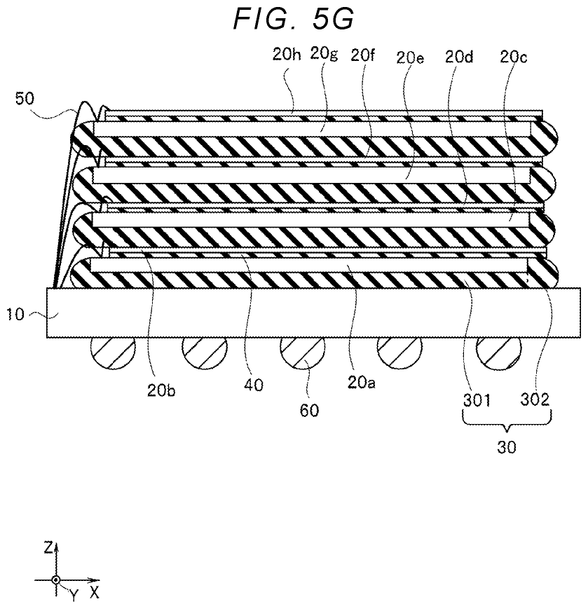

The method of manufacturing the semiconductor device 100 configured as described above will be described with reference to FIGS. 3, 4, and 5A to 5G. FIGS. 3 and 4 are flowcharts showing manufacturing steps of the semiconductor device 100 according to the first embodiment. In addition, FIGS. 5A to 5G are cross-sectional views schematically showing manufacturing steps according to the semiconductor device 100 of the first embodiment. FIGS. 5A to 5G show cross-sectional structures in the middle steps when the semiconductor device 100 shown in FIG. 1 is manufactured with reference to the flowcharts of FIGS. 3 and 4.

First, for each of the semiconductor chips 20, based on the configuration of a semiconductor chip 20 to be stacked on the wiring board 10, a film-like adhesive is selected to be attached to the rear surface of the semiconductor chip (S1). As the film-like adhesive to be attached to the rear surface of each semiconductor chip 20, any one of the first film-like adhesive 30 and the second film-like adhesive 40 is selected. A detailed procedure of S1 will be described with reference to FIG. 4. The procedure shown in FIG. 4 is performed for each semiconductor chip 20. For example, as shown in FIG. 1, when eight semiconductor chips 20a to 20h are stacked, the procedure shown in FIG. 4 is performed for each chip.

First, the thickness of the target semiconductor chip 20 is checked (S11). The thicknesses of the plurality of semiconductor chips 20 mounted on the wiring board 10 are not all equal. The thickness of each semiconductor chip 20 depends on the structure of the circuit formed in the chip. The film-like adhesive to be attached to the rear surface of the target semiconductor chip 20 is selected in consideration of the thickness of the chip. For example, when the thickness of the target semiconductor chip 20 is large compared to others of the semiconductor chips 20 (YES in S11), the process of FIG. 4 proceeds to S16, and the first film-like adhesive 30 is selected.

On the other hand, when the thickness of the target semiconductor chip 20 is thin compared to others of the semiconductor chips 20 (NO in S11), it is checked whether the target semiconductor chip 20 is disposed in the uppermost layer of the semiconductor device 100, i.e., is the uppermost semiconductor chip 20 in the Z direction (S12). When the target semiconductor chip 20 is disposed in the uppermost layer (YES in S12), the process of FIG. 4 proceeds to S15, and the second film-like adhesive 40 is selected. On the other hand, when the target semiconductor chip 20 is disposed in a layer other than the uppermost layer (NO in S12), the presence or absence of the overhang region 201 of the semiconductor chip 20 disposed directly above is checked (S13). When there is no such overhang region 201 (NO in S13), the process proceeds to S15, and the second film-like adhesive 40 is selected. On the other hand, when such overhang region 201 is present (YES in S13), it is checked whether the first film-like adhesive is selected as the adhesive to be attached to the rear surface of the semiconductor chip 20 disposed directly above the target semiconductor chip 20 (S14). When the first film-like adhesive 30 is selected (YES in S14), the process proceeds to S15, and the second film-like adhesive 40 is selected as the adhesive to be attached to the target semiconductor chip 20. On the other hand, when the first film-like adhesive 30 is not selected (NO in S14), the process proceeds to S16, and the first film-like adhesive 30 is selected as the adhesive to be attached to the target semiconductor chip 20.

For example, when eight semiconductor chips 20 are stacked on the wiring board 10 while being offset from each other as shown in FIG. 1, and when the film-like adhesive to be attached to the rear surface of each of the semiconductor chips 20 is selected according to the procedure shown in FIG. 4, the first film-like adhesive 30 is selected for the semiconductor chips 20a, 20c, 20c, and 20g, and the second film-like adhesive 40 is selected for the semiconductor chips 20b, 20d, 20f, and 20h.

Returning to the procedure of FIG. 3, subsequently, the film-like adhesive 30 or 40 selected in S1 is attached to the rear surface of one of the semiconductor chips 20 that is in a lowermost layer of the semiconductor device 100 (that is the lowermost semiconductor chip 20 in the Z direction), and is disposed on the first surface 10a of the wiring board 10 (S2). For example, as shown in FIG. 5A, the semiconductor chip 20a having the first film-like adhesive 30 attached to its rear surface is disposed on the first surface 10a of the wiring board 10. At this time, the first film-like adhesive 30 has the same shape as the rear surface of the semiconductor chip 20a and has a substantially uniform thickness.

Next, the film-like adhesive is cured by heat-pressing (S3). In S3, for example, as shown in FIG. 5B, a mount collet 80 is applied to the front surface of the semiconductor chip 20a to heat and apply pressure to the front surface. Since the first film-like adhesive 30 is thick and has a low viscosity, the semiconductor chip 20a is embedded in the first film-like adhesive 30 in the process of heat-pressing. As a result, the first film-like adhesive 30 is extruded outward from the peripheral edge of the semiconductor chip 20a. At this time, the first film-like adhesive 30 is extended in a direction parallel to the XY plane and is also extended upward in the Z direction. When the heat-pressing is completed, for example, as shown in FIG. 5C, the first film-like adhesive 30 changes shape. That is, the first film-like adhesive 30 has a recessed shape formed of a base portion 301 that is under the rear surface of the semiconductor chip 20a and covers the entire rear surface, and an extension portion 302 that extends toward the outside of the semiconductor chip 20a and has a thickness in the Z direction greater than that of the base portion 301. For example, as shown in FIG. 2, the first film-like adhesive 30 is extended such that the difference between the thickness of the extension portion 302 and the thickness of the base portion 301 is about T4 (≈the thickness T2 of the semiconductor chip 20a). When T2 is 120 μm or less, the thickness of the base portion 301 after the extension may be thinned to about 3 μm. When the S3 is completed, the first film-like adhesive 30 is cured, and the wiring board 10 and the semiconductor chip 20a are brought into close contact with each other.

Subsequently, the adhesive selected in S1 for the semiconductor chip 20 to be stacked next is attached to the rear surface thereof, and the next semiconductor chip 20 is disposed on the front surface of the semiconductor chip 20 that is positioned on a current uppermost layer of the semiconductor device 100(S4). For example, in a case of manufacturing the semiconductor device 100 having the structure shown in FIG. 1, the semiconductor chip 20b to which the second film-like adhesive 40 is attached is disposed on the front surface of the semiconductor chip 20a. Next, the film-like adhesive selected for the “next” semiconductor device of S4, is cured by heat-pressing (S5). In S5, for example, as shown in FIG. 5D, the mount collet 80 is applied to the front surface of the semiconductor chip 20b, to heat and apply pressure to the front surface. Since the second film-like adhesive 40 is thin and has a high viscosity, the shape thereof does not change even in the process of heat-pressing, and the semiconductor chip 20b is not embedded.

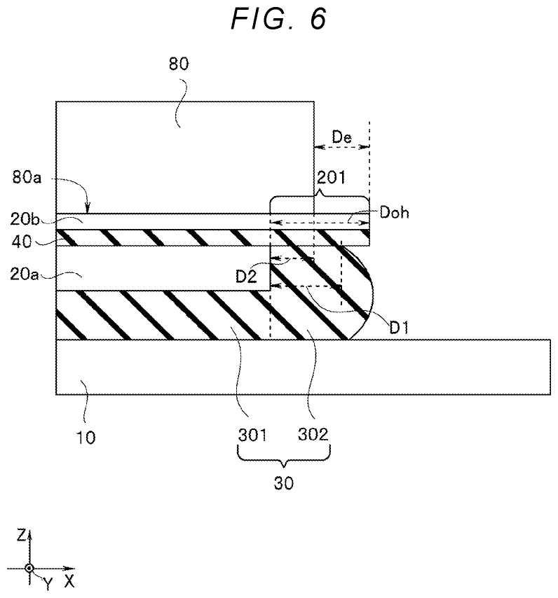

FIG. 6 is a diagram showing a positional relationship between the extension portion 302 and a pressing surface of the mount collet 80 according to the first embodiment. The pressing surface 80a of the mount collet 80 is smaller than the front surface of the semiconductor chip 20 (in FIG. 6, the semiconductor chip 20b) to be pressed. The distance De between an end portion of the pressing surface 80a and an end portion of the semiconductor chip 20b is set to, for example, about 100 μm to 500 μm. When De<Doh, as shown in FIG. 6, the end portion of the pressing surface 80a is positioned within the overhang region 201. In this case, in S5, when the semiconductor chip 20b is heat-pressed with respect to the semiconductor chip 20a, a downward pressure is applied to the portion of the overhang region 201 that is in close contact with the pressing surface 80a. Due to the downward pressure, in the absence of support, the overhang region 201 may be deflected downward, and the semiconductor chip 20b may be cracked. Accordingly, in the semiconductor device 100 of the first embodiment, the extension portion 302 is formed below the overhang region 201, and the extension portion 302 has a function of supporting the overhang region 201. That is, even when the downward pressure is applied to the overhang region 201, the overhang region 201 is prevented from being deflected downward by means of the extension portion 302. Therefore, the extension portion 302 prevents the semiconductor chip 20b from being cracked.

The end portion of the extension portion 302 (specifically, the end portion of the upper surface of the extension portion 302, which is in contact with the lower surface of the film-like adhesive 40) is preferably closer to the end portion of the semiconductor chip 20b than to the end portion of the pressing surface 80a. For example, as shown in FIG. 6, when a distance from the end portion of the semiconductor chip 20a to the end portion of the extension portion 302 is set to D1, and a distance from the end portion of the semiconductor chip 20a to the end portion of the pressing surface 80a is set to D2, it is preferable that the extension portion 302 satisfies a relationship of D2<D1 (<Doh).

Next, as shown in FIG. 5E, the semiconductor chips 20a and 20b and the wiring board 10 are bonded to each other with the conductive wire 50 (S6). S6 is performed for any of the semiconductor chips 20 stacked on the wiring board 10 for which the bonding has not yet been performed. In addition, it is not required to perform S6 immediately after S5 for each of the semiconductor chips 20 to be stacked. S4 and S5 may be performed for a first (lower) one of the semiconductor chips 20, then S4 and S5 may be performed for a next (upper) one of the semiconductor chips 20, and then S6 may be performed for both.

When at least one of semiconductor chips 20 reamins to be stacked (NO in S7), the procedures of S4 to S6 are repeated for another semiconductor chip 20, and the semiconductor chip 20 is stacked on the upper layer. For example, when six semiconductor chips 20c to 20h are stacked above the semiconductor chip 20b, the procedures S4 to S6 are performed for each of the semiconductor chips 20c to 20h. In the step (S5) of stacking each of the semiconductor chips 20c, 20c, and 20g, the first film-like adhesive 30 attached to the rear surface thereof is extended to the outside of the chip, and the extension portion 302 is formed, in the same manner as in the step (S3) of adhering the semiconductor chip 20a to the wiring board 10. The extension portions 302 of the semiconductor chips 20c, 20e, and 20g prevent the overhang regions 201 of the semiconductor chips 20d, 20f, and 20h from being deflected downward, and prevent the semiconductor chips 20d, 20f, and 20h from being cracked.

On the other hand, as shown in FIG. 5F, when all the semiconductor chips 20 have been stacked (YES in S7), after solder balls 60 are provided on the second surface 10b of the wiring board 10 as shown in FIG. 5G (S8), the stacked semiconductor chips 20, the first film-like adhesive 30, the second film-like adhesive 40, and the bonded conductive wire 50 are sealed with the mold resin 70 (S9), and thus, for example, the semiconductor device 100 having the structure shown in FIG. 1 is completed.

In recent years, there has been an increasing demand for making semiconductor devices thinner. Due to the decreased thickness, the flexural strength of semiconductor chips have tended to decrease. When a plurality of semiconductor chips are stacked while being offset from each other, there has been a concern that cracking may occur in overhang regions of some of the semiconductor chips when an external stress is applied to the semiconductor chips.

According to the first embodiment, when considering two of the semiconductor chips 20 adjacent to each other in the Z direction, when the upper semiconductor chip 20 has a low flexural strength, the overhang region 201 of the upper semiconductor chip 20 is formed, and the second film-like adhesive 40 formed of a thin film such as DAF is attached to the rear surface of the upper semiconductor chip 20. The first film-like adhesive 30 attached to the rear surface of the lower semiconductor chip 20 is configured as follows. The first film-like adhesive 30 is configured with a base portion 301 covering the rear surface of the lower semiconductor chip 20 and an extension portion 302 extending outward from the peripheral edge (chip end) of the lower semiconductor chip 20. The thickness of the extension portion 302 is greater than the thickness of the base portion 301. At least a part of the extension portion 302 is in contact with the overhang region 201 of the upper semiconductor chip 20 via the second film-like adhesive 40. When the upper semiconductor chip 20 is brought into close contact with the lower semiconductor chip 20, even though downward pressure is applied to the upper semiconductor chip 20, the overhang region 201 is supported by the extension portion 302 and the overhang region 201 is prevented from being deflected downward. This prevents the upper semiconductor chip 20 from being cracked. In this way, the semiconductor device 100 is made thinner while preventing some of the semiconductor chips 20 therein from being cracked.

### Second Embodiment

Next, a semiconductor device according to a second embodiment will be described. Many features are the same as those in the first embodiment, and the description of such features will be omitted.

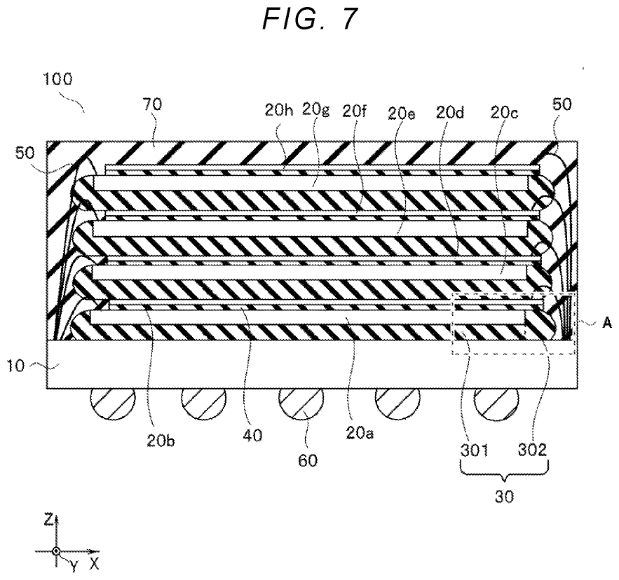

In the first embodiment, the conductive wire 50 connecting the semiconductor chips 20a to 20h and the wiring board 10 is connected to the left-hand side (in the X direction) of the front surface of each chip. However, as shown in the second embodiment, the conductive wire 50 may be connected to other places such as the right-hand side (in the X direction) of the front surface of each chip. FIG. 7 is a cross-sectional view schematically showing the semiconductor device according to the second embodiment. In the semiconductor device 100 shown in FIG. 7, the conductive wires 50 connecting the semiconductor chips 20a, 20c, 20c, and 20g and the wiring board 10 are connected to the right-hand side (in the X direction) of the front surface of each chip, but the conductive wires 50 connecting the semiconductor chips 20b, 20d, 20f, and 20h and the wiring board 10 are connected to the left-hand side (in the X direction) of the front surface of each chip.

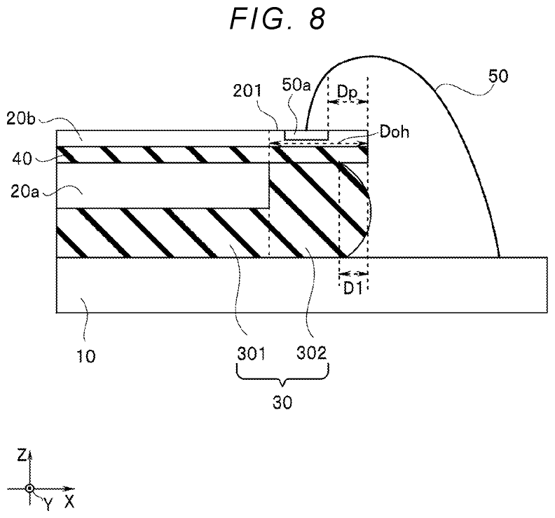

FIG. 8 is a diagram showing a positional relationship between an extension portion and a pad according to the second embodiment. FIG. 8 is an enlarged sectional view of the portion A of FIG. 7. In FIG. 8, the semiconductor chips 20c to 20h, the first film-like adhesive 30 and the second film-like adhesive 40 provided on the semiconductor chips 20c to 20h, the conductive wire 50 connected to the chips other than the semiconductor chip 20b, and the mold resin 70 are not shown. A pad 50a for electrically connecting the conductive wire 50 and the internal circuit of the semiconductor chip 20b is formed on the front surface of the semiconductor chip 20b. A distance Dp between the end portion of the pad 50a and the end portion of the semiconductor chip 20b is set to about 30 μm to 150 μm. When Dp<Doh, as shown in FIG. 8, the pad 50a is positioned on the overhang region 201. In this case, in S6, when the conductive wire 50 is bonded to the semiconductor chip 20b, a downward pressure is applied to the pad 50a of the overhang region 201. Due to the downward pressure, in the absence of support, the overhang region 201 may be deflected downward, and the semiconductor chip 20b may be cracked. Accordingly, in the semiconductor device 100 of the second embodiment, the extension portion 302 is formed below the overhang region 201, and at least a part of the extension portion 302 is in contact with the lower surface of the second film-like adhesive 40. As described above, the extension portion 302 and the second film-like adhesive 40 have a contact region, and the extension portion 302 holds the overhang region 201 in the contact region. That is, even when the downward pressure is applied to the overhang region 201, the overhang region 201 is prevented from being deflected downward by means of the extension portion 302. Therefore, it is possible to prevent the semiconductor chip 20b from being cracked. As described above, in the second embodiment, it is possible to obtain the same advantages as those in the first embodiment.

The end portion of the extension portion 302 (specifically, the end portion of the surface of the extension portion 302, which is in contact with the lower surface of the film-like adhesive 40) is preferably closer to the end portion of the semiconductor chip 20b than the end portion of the pad 50a is. As shown in FIG. 8, when a distance from the end portion of the semiconductor chip 20b to the surface of the end portion of the extension portion 302 is set to D1, it is preferable that the extension portion 302 satisfies a relationship of D1<Dp (<Doh).

### Third Embodiment

Next, a semiconductor device according to a third embodiment will be described. Many features are the same as those in the first embodiment, and the description of such features will be omitted.

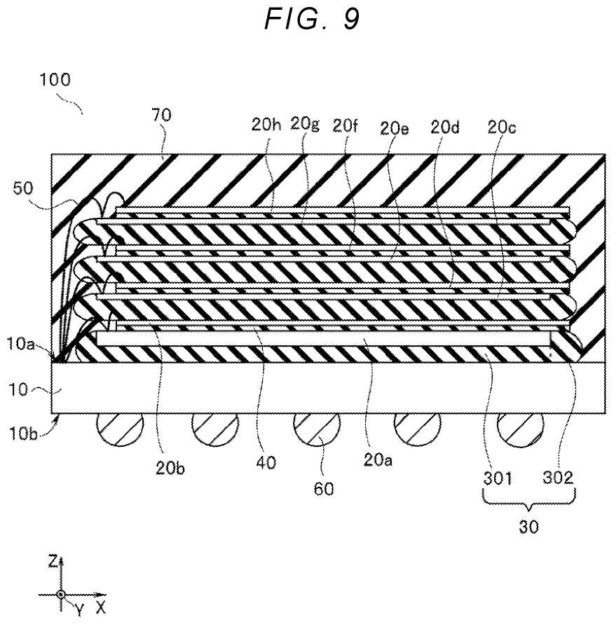

In the first embodiment, thick semiconductor chips 20 and thin semiconductor chips 20 are alternately stacked, but as shown in the third embodiment, it is possible to stack a plurality of the thin semiconductor chips 20 in a row. FIG. 9 is a cross-sectional view schematically showing the semiconductor device according to the third embodiment. In FIG. 9, only the semiconductor chip 20a in the lowermost layer is thick, and the semiconductor chips 20b to 20h from the second lowest layer to the uppermost layer of the semiconductor device 100 are thin. It is also possible to make the semiconductor chip 20a in the lowermost layer of the semiconductor device 100 thin. However, in consideration of the fact that the semiconductor chip 20a is brought into close contact with the first surface 10a having an uneven portion formed on the front surface thereof and having low flatness, the semiconductor chip 20a benefits from having increased flexural strength from the viewpoint of preventing chip cracking. Therefore, it is preferable that the semiconductor chip 20a disposed in the lowermost layer of the semiconductor device 100 is relatively thick.

As shown in FIG. 9, even when the thin semiconductor chips 20b to 20h are stacked, the adhesive to be attached to each of the rear surfaces is appropriately selected in accordance with the procedure shown in FIG. 4, and the extension portion 302 is formed, whereby it is possible to prevent the overhang region 201 from being deflected downward in the heat-pressing (S5) and the bonding (S6) steps. Therefore, it is possible to prevent the semiconductor chips 20b to 20h from being cracked. As described above, in the third embodiment, it is possible to obtain the same advantages as those in the first embodiment. Furthermore, since the semiconductor chips 20b to 20h are thin, the height of the semiconductor device 100 in the Z direction is reduced as compared with the height of the semiconductor device 100 in the Z direction of the first embodiment.

### Fourth Embodiment

Next, a semiconductor device according to a fourth embodiment will be described. Many features are the same as those in the first embodiment, and the description of such features will be omitted.

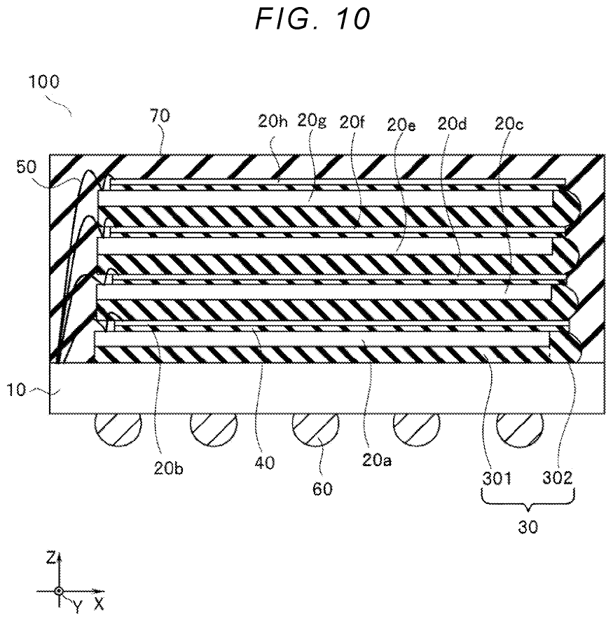

FIG. 10 is a cross-sectional view schematically showing the semiconductor device according to the fourth embodiment. In the semiconductor device 100 shown in FIG. 1, the extension portion 302 is formed on the outside from both ends of semiconductor chips 20 in the X direction. However, as shown in FIG. 10, the extension portion 302 may be provided only on one side in the X direction where the overhang region 201 is formed in the semiconductor chips 20 disposed directly above. As described above, in the fourth embodiment, it is possible to obtain the same advantages as those in the first embodiment. Further, a width in the X direction of the semiconductor device 100 of the first embodiment may be reduced.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first semiconductor chip on which a first adhesive having an insulating property is attached to a rear surface thereof; and
a second semiconductor chip on which a second adhesive having an insulating property is attached to a rear surface thereof, wherein
the second semiconductor chip is attached to a front surface of the first semiconductor chip via the second adhesive,
the second semiconductor chip has an overhang region that does not overlap the first semiconductor chip when viewed in a first direction orthogonal to the front surface of the first semiconductor chip, and
the first adhesive includes a base portion that covers the entire rear surface of the first semiconductor chip and also includes an extension portion that extends in a second direction parallel to the front surface of the first semiconductor chip, from the base portion of the first adhesive to beyond an edge of the first semiconductor chip, at least a part of the extension portion of the first adhesive overlapping the overhang region of the second semiconductor chip when viewed in the first direction.

2. The semiconductor device according to claim 1, wherein the extension portion of the first adhesive includes a thermosetting resin.

3. The semiconductor device according to claim 1, wherein an upper surface of the extension portion of the first adhesive has a contact region in contact with the second adhesive.

4. The semiconductor device according to claim 3, wherein
the overhang region of the second semiconductor chip includes a pad that is connected to a wiring board of the semiconductor device via a conductive wire, and
the distance in the second direction, from an edge of the second semiconductor chip on a side of the second semiconductor chip that does not overlap the first semiconductor chip when viewed in the first direction, to the contact region, is shorter than the distance from the edge of the second semiconductor chip to the pad.

5. The semiconductor device according to claim 1, wherein a ratio of the thickness in the first direction of the second adhesive and the second semiconductor chip combined, to the length in the second direction of the overhang region of the second semiconductor chip, is 0.13 or more.

6. The semiconductor device according to claim 1, wherein the second semiconductor chip is thinner in the first direction than the first semiconductor chip.

7. The semiconductor device according to claim 1, further comprising:
a wiring board that is electrically connected to the first and second semiconductor chips via conductive wires, the conductive wires being connected to the same sides in the second direction of the first and second semiconductor chips.

8. The semiconductor device according to claim 1, further comprising:
a wiring board that is electrically connected to the first and second semiconductor chips via conductive wires, the conductive wires being connected to opposite sides in the second direction of the first and second semiconductor chips.

9. The semiconductor device according to claim 1, further comprising:
a third semiconductor chip on which a third adhesive having an insulating property is attached to a rear surface thereof, wherein the third semiconductor chip is attached to a front surface of the second semiconductor chip via the third adhesive.

10. The semiconductor device according to claim 9, further comprising:
a fourth semiconductor chip on which a fourth adhesive having an insulating property is attached to a rear surface thereof, wherein the fourth semiconductor chip is attached to a front surface of the third semiconductor chip via the fourth adhesive.

11. The semiconductor device according to claim 10, wherein the fourth semiconductor chip has an overhang region that does not overlap the third semiconductor chip when viewed in the first direction.

12. The semiconductor device according to claim 11, wherein the third adhesive includes a base portion that covers the entire rear surface of the third semiconductor chip and also includes an extension portion that extends in the second direction from the base portion of the third adhesive to beyond an edge of the third semiconductor chip, at least a part of the extension portion of the third adhesive overlapping the overhang region of the fourth semiconductor chip when viewed in the first direction.

13. The semiconductor device according to claim 10, wherein the thickness of the first semiconductor chip is greater than the thicknesses of each of the second and fourth semiconductor chips when viewed in the first direction, and the thickness of the third semiconductor chip is greater than the thicknesses of each of the second and fourth semiconductor chips when viewed in the first direction.

14. The semiconductor device according to claim 10, wherein the thickness of the first semiconductor chip is greater the thicknesses of each of the second, third, and fourth semiconductor chips when viewed in the first direction.

15. The semiconductor device according to claim 1, wherein the first adhesive includes an additional extension portion that extends in the second direction from the base portion of the first adhesive to beyond an opposite edge of the first semiconductor chip.

16. The semiconductor device according to claim 1, wherein the thickness of the extension portion of the first adhesive is greater than the thickness of the base portion of the first adhesive when viewed in the first direction.

17. The semiconductor device according to claim 1, wherein the first and second adhesives are films.

18. The semiconductor device according to claim 17, wherein the first adhesive is one of film on wire (FOW) and film on die (FOD).

19. The semiconductor device according to claim 17, wherein the second adhesive is die attach film (DAF).

20. The semiconductor device according to claim 17, wherein the first adhesive has a thickness in the first direction of 40 to 150 μm, and the second adhesive has a thickness in the first direction of 25 μm or less.
